(19) United States
(12) Patent Application Publication
(10) Pub. No.: US 2024/0069793 A1
(43) Pub. Date: Feb. 29, 2024

(54) EFFICIENT WRITE OPERATION FOR SRAM

(71) Applicant: MediaTek Singapore Pte. Ltd., Singapore (SG)

(72) Inventors: Manish TRIVEDI, Bengaluru KA (IN); Jaswinder SIDHU, Bengaluru KA (IN); Ramesh HALLI, Bengaluru KA (IN)

(21) Appl. No.: 18/306,572

(22) Filed: Apr. 25, 2023

(30) Foreign Application Priority Data
Aug. 24, 2022 (IN) 202221048310

(51) Int. Cl. G06F 3/06

(52) U.S. Cl. CPC G06F 3/0655; G06F 3/0604; G06F 3/0673

(57) ABSTRACT

A circuit including a memory cell, a pair of bit lines, a precharge circuit, a multiplexer, and a pull-up circuit is provided herein. The bit lines are coupled to the memory cell. The precharge circuit is coupled between the bit lines and configured to precharge each of the bit lines to approximately a first supply voltage to begin the write operation. The multiplexer is configured to select which bit line is a zero bit driven to a low logic level during the write operation and after the precharge circuit is turned off. After the write operation begins, the pull-up circuit is coupled to the bit lines and configured to select which bit line is a non-zero bit line driven to a high logic level.

### CROSS REFERENCE TO RELATED APPLICATIONS

This Application claims priority of India Patent Application No. 202221048310, filed on Aug. 24, 2022, the entirety of which is incorporated by reference herein.

### BACKGROUND OF THE INVENTION

### Field of the Invention

The disclosure is generally related to memory systems, and more particularly it is related to apparatuses for performing write operations on memory systems in a dual-rail configuration.

### Description of the Related Art

SRAM (Static Random Access Memory) is a type of memory commonly used in digital circuits, and its performance can be affected by power management techniques such as DVFS (Dynamic Voltage and Frequency Scaling) and dual-rail configuration. DVFS can impact SRAM performance by causing increased leakage current and variations in timing due to changes in voltage and frequency. This can lead to reduced stability and poor reliability of the memory, potentially causing corruption or loss of data.

Similarly, dual-rail configuration can also affect SRAM performance due to the increased complexity of the power supply system. At lower voltages, SRAM may become more sensitive to noise and timing variations, which can result in challenges with writing data accurately. Write operations may also become more time-consuming and require more power, leading to increased write latencies and decreased write speeds.

For the robustness of performing write operations on SRAM with lower voltages, apparatuses for performing write operations on SRAM should be optimized.

### BRIEF SUMMARY OF THE INVENTION

For solving above problems, the invention provides memory circuits and methods for performing write operations on a memory cell. Since a differential writing scheme is performed on the selected memory cell as provided herein, the robustness and the speed of performing write operations on a memory cell with lower periphery voltage can be improved simultaneously.

In an embodiment, a circuit comprising a memory cell, a pair of bit lines, a precharge circuit, a multiplexer, and a pull-up circuit is provided. The pair of bit lines is coupled to the memory cell. The precharge circuit is coupled between the pair of bit lines. The precharge circuit is configured to precharge each of the bit lines to approximately a first supply voltage to begin the write operation. The multiplexer is configured to select which one of the pair of bit lines is a zero bit driven to a low logic level during the write operation and after the precharge circuit is turned off. The pull-up circuit is coupled to the pair of bit lines. After the write operation begins, the pull-up circuit is configured to select which one of the pair of bit lines is a non-zero bit line driven to a high logic level.

According to an embodiment of the invention, the memory cell is supplied with a second supply voltage, wherein the second supply voltage either equals or exceeds the first supply voltage.

According to an embodiment of the invention, the pull-up circuit charges the non-zero bit to approximately the first supply voltage according to the input data.

According to an embodiment of the invention, the multiplexer further comprises a pair of pass transistors. Each of the pair of pass transistors is coupled to different one of the pair of bit lines. The pair of pass transistors select which one of the pair of bit lines is the zero bit during the write operation by coupling the zero bit to a ground according to input data.

According to an embodiment of the invention, the pull-up circuit further comprises a first stack of pull-up transistors and a second stack of pull-up transistors. Each of the first stack of pull-up transistors and the second stack of pull-up transistors is coupled to different one of the pair of bit lines. After the write operation begins, the first stack of pull-up transistors and the second stack of pull-up transistors select which one of the pair of bit lines is the non-zero bit line by charging the non-zero bit to approximately the first supply voltage according to the input data.

According to an embodiment of the invention, the circuit further comprises a write driver. The write driver comprises a first logic gate and a second logic gate. The first logic gate performs a first logic operation on the input data and a select signal to generate a zero-bit signal so as to turn on the corresponding one of the pair of pass transistors for coupling the zero bit to the ground. The second logic gate performs a second logic operation on the input data and the select signal to generate an non-zero-bit signal so as to turn on the corresponding first or second stack of pull-up transistors for charging the non-zero bit to approximately the first supply voltage. The zero-bit signal is the inverse of the non-zero-bit signal.

According to an embodiment of the invention, the first stack of pull-up transistors comprises a first transistor and a second transistor. The first transistor is coupled to the first supply voltage and controlled by the non-zero-bit signal. The second transistor is coupled between the first transistor and the non-zero bit and controlled by the zero bit. The second stack of pull-up transistors comprises a third transistor and a fourth transistor. The third transistor is coupled to the first supply voltage and controlled by the zero-bit signal. The fourth transistor is coupled between the third transistor and the zero bit and is controlled by the non-zero bit. The first transistor and the second transistor are turned on to drive the non-zero bit to the high logic level. The third transistor is turned off based on the zero-bit signal.

According to an embodiment of the invention, the pair of pass transistors select the zero bit coupled to the ground based on the zero-bit signal.

According to an embodiment of the invention, the circuit further comprises a negative boost circuit. The negative boost circuit is coupled between the multiplexer and the ground. When the negative boost circuit is turned on, the negative boost circuit couples the multiplexer to the ground. When the negative boost circuit is turned off, the negative boost circuit provides a negative voltage to the multiplexer.

According to another embodiment of the invention, the circuit further comprises a write driver. The write driver is coupled to the pair of bit lines through the multiplexer. The write driver is configured to drive the zero bit to the low logic level and to drive the non-zero bit to the high logic level.

According to another embodiment of the invention, the multiplexer further comprises a pair of pass transistors. Each of the pair of pass transistors is coupled to different one of the pair of bit lines. When the memory cell is selected, the pair of pass transistors are turned on so that the write driver is coupled to the pair of bit lines.

According to another embodiment of the invention, the pull-up circuit further comprises a pair of pull-up transistors and a pair of cross-pullup transistors. Each of the pair of pull-up transistors is coupled to different one of the pair of bit lines. Each of the pair of cross-pullup transistors is coupled to different one of the pair of bit lines. One of the pair of pull-up transistors is configured to charge the non-zero bit to approximately the first supply voltage based on a zero-bit signal and the other of the pair of pull-up transistors is turned off. One of the pair of cross-pullup transistors is configured to charge the non-zero bit to approximately the first supply voltage based on the zero bit and the other of the pair of cross-pullup transistors is turned off. The write driver configured to drive the zero bit to the low logic level based on the zero-bit signal.

In another embodiment, a method for performing a write operation on a memory cell is provided. The method comprises the following steps. A pair of bit lines coupled to the memory cell is precharged to approximately a first supply voltage to begin the write operation. After the precharging of the pair of bit lines is turned off, which one of the pair of bit lines is a zero bit driven to a low logic level is selected. After the write operation begins, which one of the pair of bit lines is a non-zero bit line driven to a high logic level is selected.

According to an embodiment of the invention, the memory cell is supplied with a second supply voltage. The second supply voltage either equals or exceeds the first supply voltage.

According to an embodiment of the invention, the step of selecting which one of the pair of bit lines is the zero bit driven to the low logic level further comprises the following step. Which one of the pair of bit lines is the zero bit is selected by coupling the zero bit to a ground according to input data.

According to an embodiment of the invention, the step of selecting which one of the pair of bit lines is the non-zero bit line driven to the high logic level further comprises the following step. Which one of the pair of bit lines is the non-zero bit line by charging the non-zero bit to approximately the first supply voltage is selected according to the input data

According to an embodiment of the invention, the method further comprises the following steps. A first logic operation is performed on the input data and a select signal to generate a zero-bit signal. The zero bit is coupled to the ground according to the zero-bit signal. A second logic operation is performed on the input data and the select signal to generate a non-zero-bit signal. The non-zero bit is charged with the first supply voltage according to the non-zero-bit signal. The zero-bit signal is the inverse of the non-zero-bit signal.

According to an embodiment of the invention, the non-zero bit is driven to the high logic level by a stack of pull-up transistors. The step of selecting which one of the pair of bit lines is the non-zero bit line driven to the high logic level further comprises the following steps. The stack of pull-up transistors is turned on based on the zero bit and the non-zero-bit signal. The non-zero bit is charged to approximately the first supply voltage due to the stack of pull-up transistors being turned on.

According to another embodiment of the invention, the step of selecting which one of the pair of bit lines is the zero bit driven to the low logic level further comprises the following steps. A zero-bit signal is generated based on input data by a write driver. The zero-bit signal is provided to the zero bit to drive the zero bit to the low logic level.

According to another embodiment of the invention, the step of selecting which one of the pair of bit lines is the non-zero bit line driven to the high logic level further comprises the following steps. A non-zero-bit signal is generated based on the input data by using the write driver, where the non-zero-bit signal is the inverse of the zero-bit signal. The non-zero-bit signal is provided to the non-zero bit to drive the non-zero bit to the high logic level. The non-zero bit is charged to approximately the first supply voltage by a pull-up transistor according to the zero-bit signal. The non-zero bit is further charged to approximately the first supply voltage by using a cross-pullup transistor according to the zero bit.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIG. 1 is a circuit diagram of a memory circuit in accordance with an embodiment of the invention.

FIG. 2 illustrates a signal diagram of the memory circuit shown in FIG. 1 during the write operation in accordance with an embodiment of the invention.

FIG. 3 is a circuit diagram of a memory circuit in accordance with another embodiment of the invention.

FIG. 4 is a circuit diagram of a memory circuit in accordance with yet another embodiment of the invention.

FIG. 5 is a flow chart of a method for performing a write operation on a memory cell in accordance with an embodiment of the invention.

### DETAILED DESCRIPTION OF THE INVENTION

The following description is made for the purpose of illustrating the general principles of the disclosure and should not be taken in a limiting sense. The scope of the disclosure is determined by reference to the appended claims.

In the following detailed description, for purposes of explanation, numerous specific details and embodiments are set forth in order to provide a thorough understanding of the present disclosure. The use of like and/or corresponding numerals in the drawings of different embodiments does not suggest any correlation between different embodiments.

In addition, in some embodiments of the present disclosure, terms concerning attachments, coupling and the like, such as “connected” and “interconnected,” refer to a relationship wherein structures are secured or attached to one another either directly or indirectly (for example, electrically connection) via intervening structures, as well as both movable or rigid attachments or relationships, unless expressly described otherwise.

In addition, in this specification, relative spatial expressions are used. For example, “lower”, “bottom”, “higher” or “top” are used to describe the position of one element relative to another. It should be appreciated that if a device is flipped upside down, an element that is “lower” will become an element that is “higher”.

It should be understood that, although the terms first, second, third etc. may be used herein to describe various elements, components, regions, layers, portions and/or sections, these elements, components, regions, layers, portions and/or sections should not be limited by these terms. These terms are only used to distinguish one element, component, region, layer, portion or section from another element, component, region, layer or section. Thus, a first element, component, region, layer, portion or section in the specification could be termed a second element, component, region, layer, portion or section in the claims without departing from the teachings of the present disclosure.

It should be understood that this description of the exemplary embodiments is intended to be read in connection with the accompanying drawings, which are to be considered part of the entire written description. The drawings are not drawn to scale. In addition, structures and devices are shown schematically in order to simplify the drawing.

The terms “approximately”, “about” and “substantially” typically mean a value is within a range of +/−20% of the stated value, more typically a range of +/−10%, +/−5%, +/−3%, +/−2%, +/−1% or +/−0.5% of the stated value. The stated value of the present disclosure is an approximate value. Even there is no specific description, the stated value still includes the meaning of “approximately”, “about” or “substantially”.

Unless defined otherwise, all technical and scientific terms used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined.

In addition, in some embodiments of the present disclosure, terms concerning attachments, coupling and the like, such as “connected” and “interconnected,” refer to a relationship wherein structures are secured or attached to one another either directly or indirectly (for example, electrically connection) via intervening structures, as well as both movable or rigid attachments or relationships, unless expressly described otherwise.

In the drawings, similar elements and/or features may have the same reference number. Various components of the same type can be distinguished by adding letters or numbers after the component symbol to distinguish similar components and/or similar features.

In addition, in some embodiments of the present disclosure, terms concerning attachments, coupling and the like, such as “connected” and “interconnected,” refer to a relationship wherein structures are secured or attached to one another either directly or indirectly (for example, electrically connection) via intervening structures, as well as both movable or rigid attachments or relationships, unless expressly described otherwise.

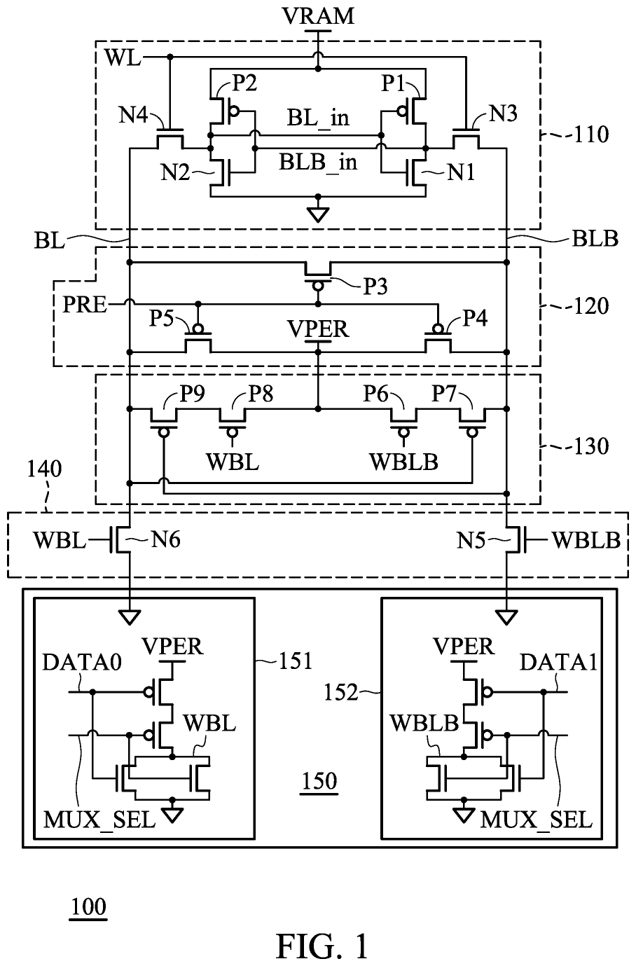

FIG. 1 is a circuit diagram of a memory circuit in accordance with an embodiment of the invention. As shown in FIG. 1, the memory circuit 100 includes a memory cell 110, a precharge circuit 120, a pull-up circuit 130, a multiplexer 140, and a write driver 150. The memory cell 110 includes a first P-type transistor P1, a first N-type transistor N1, a second P-type transistor P2, a second N-type transistor N2, a third N-type transistor N3, and a fourth N-type transistor N4.

The first P-type transistor P1 is controlled by an internal bit line BL_in and coupled between a SRAM voltage VSRAM and an inverted internal bit line BLB_in. The first N-type transistor N1 is controlled by the internal bit line BL_in and coupled between the inverted internal bit line BLB_in and a ground. The second P-type transistor P-type transistor P2 is controlled by the inverted internal bit line BLB_in and coupled between the SRAM voltage VSRAM and the internal bit line BL_in. The second N-type transistor N2 is controlled by the inverted internal bit line BLB_in and coupled between and the internal bit line BL_in and the ground.

In other words, the first P-type transistor P1 and the first N-type transistor N1 form a first inverter, and the second P-type transistor P2 and the second N-type transistor N2 form a second inverter, where the first inverter and the second inverter are cross-coupled between the internal bit line BL_in and the inverted internal bit line BLB_in. According to an embodiment of the invention, the inverted internal bit line BLB_in is the inverse of the internal bit line BL_in.

The third N-type transistor N3 is controlled by a word line WL and coupled between the inverted internal bit line BLB_in and an inverted bit line BLB. The fourth N-type transistor N4 is controlled by the word line WL and coupled between the internal bit line BL_in and a bit line BL. According to an embodiment of the invention, the memory cell 110 is selected by the word line WL coupling the internal bit line BL_in and the internal inverted bit line BLB_in to the bit line BL and the inverted bit line BLB respectively.

The precharge circuit 120 includes a third P-type transistor P3, a fourth P-type transistor P4, and a fifth P-type transistor P5. The third P-type transistor P3 is controlled by a precharge signal PRE and coupled between the bit line BL and the inverted bit line BLB. The fourth P-type transistor P4 is controlled by the precharge signal PRE and coupled between a periphery voltage PER and the inverted bit line BLB. The fifth P-type transistor P5 is controlled by the precharge signal PRE and coupled between the periphery voltage PER and the bit line BL.

According to an embodiment of the invention, the bit line BL and the inverted bit line BLB are precharged to approximately the periphery voltage VPER to begin the write operation. According to an embodiment of the invention, the periphery voltage VPER is less than the SRAM voltage VSRAM so as to reduce the overall power consumption. According to other embodiments of the invention, the periphery voltage VPER may be equal to the SRAM voltage VSRAM. Since it may cause issues with the periphery voltage VPER less than the SRAM voltage VSRAM, the periphery voltage VPER less than the SRAM voltage VSRAM is illustrated in the following paragraphs, but not intended to be limited thereto.

The pull-up circuit 130 includes a sixth P-type transistor P6, a seventh P-type transistor P7, an eighth P-type transistor P8, and a ninth P-type transistor P9. The sixth P-type transistor P6 is controlled by an inverted write bit line WBLB and coupled to the periphery voltage VPER. The seventh P-type transistor P7 is controlled by the bit line BL and coupled between the sixth P-type transistor P6 and the inverted bit line BLB. The eighth P-type transistor P8 is controlled by a write bit line WBL and coupled to the periphery voltage VPER. The ninth P-type transistor P9 is controlled by the inverted bit line BLB and coupled between the eighth P-type transistor P8 and the bit line BL.

According to an embodiment of the invention, the sixth P-type transistor P6 and the seventh P-type transistor P7 form a stack of pull-up transistors, and the eighth P-type transistor P8 and the ninth P-type transistor P9 form the other stack of pull-up transistors. The two stacks of pull-up transistors are configured to charge either the bit line BL or the inverted bit line BLB to approximately the periphery voltage VPER according to the write bit line WBL and the inverted write bit line WBLB.

The multiplexer 140 includes a fifth N-type transistor N5 and a sixth N-type transistor N6. The fifth N-type transistor N5 is controlled by the inverted write bit line WBLB and coupled between the inverted bit line BLB and the ground. The sixth N-type transistor N6 is controlled by the write bit line WBL and coupled between the bit line BL and the ground. According to an embodiment of the invention, the fifth N-type transistor N5 and the sixth N-type transistor N6 are a pair of pass transistors that select either the bit line BL or the inverted bit line BLB to be coupled to the ground according to the write bit line WBL and the inverted write bit line WBLB.

The write driver 150 includes a first NOR gate 151 and a second NOR gate 152. The first NOR gate 151 performs an NOR operation on a select signal MUX_SEL and input data DATA0 to generate the write bit line WBL. The second NOR gate 152 performs the NOR operation on the select signal MUX_SEL and inverted input data DATA1 to generate the inverted write bit line WBLB. According to an embodiment of the invention, the inverted write bit line WBLB is the inverse of the write bit line WBL, and the inverted input data DATA1 is the inverse of the input data DATA0.

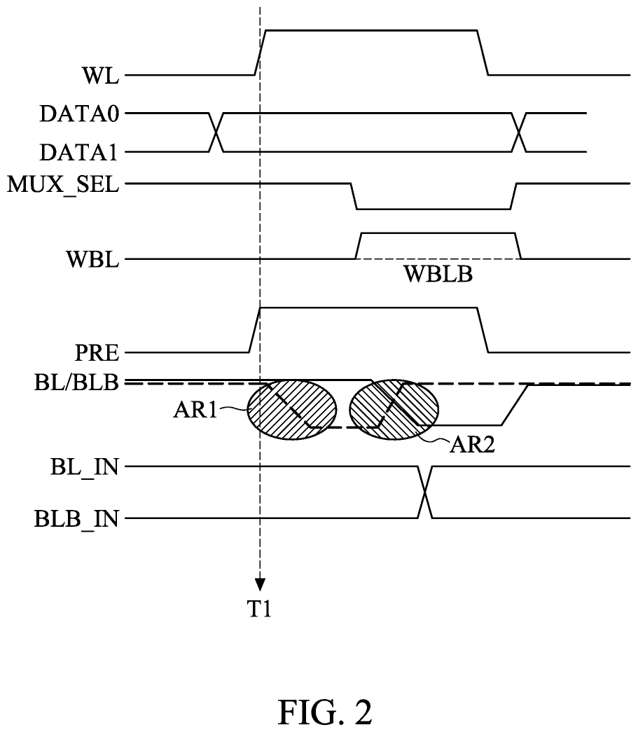

FIG. 2 illustrates a signal diagram of the memory circuit shown in FIG. 1 during the write operation in accordance with an embodiment of the invention. In the following description related to FIG. 2, it is illustrated that the internal bit line BL_in is in a high logic level, which is going to be written as a low logic level, and that the inverted internal bit line BLB_in is in the low logic level, which is going to be written as the high logic level, but not intended to be limited thereto. In other words, it is illustrated that the bit line BL is a zero bit, and the inverted bit line BLB is a non-zero bit, where the input data DATA0 is at the low logic level and the inverted input data DATA1 is at the high logic level. In addition, the write bit line WBL is a zero-bit signal for writing the bit line BL to the low logic level, and the inverted write bit line WBLB is a non-zero-bit signal for writing the inverted bit line BLB to the high logic level.

As shown in FIG. 2, before the memory cell 110 is selected by the word line WL, the precharge circuit 120 has precharged the bit line BL and the inverted bit line BLB to approximately the periphery voltage VPER to begin the write operation. At the first time T1, the precharge signal PRE goes high to turn off the precharge circuit 120, and the word line WL goes high to select the memory cell 110 for the write operation. In addition, the input data DATA0 and the inverted input data DATA1 have reached to their respective steady states before the word line WL goes high.

When the precharge signal PRE goes high, the data stored in the inverted internal bit line BLB_in, which is the low logic level for illustration, discharges the inverted bit line BLB due to the third N-type transistor N3 turned on by the word line WL as indicated by the first area AR1. As the select signal MUX_SEL goes low and the input data DATA0 is the low logic level (as illustrated), the first NOR gate 151 performs the NOR operation on the select signal MUX_SEL and the input data DATA0 to generate the write bit line WBL at the high logic level, i.e., approximately the periphery voltage VPER, to turn on the sixth N-type transistor N6 for pulling the bit line BL down to the ground.

On the other hand, the second NOR gate 152 performs the NOR operation on the select signal MUX_SEL and the inverted input data DATA1 to generate the inverted write bit line WBLB at the low logic level, i.e., approximately the ground level to turn on the sixth P-type transistor P6. In addition, since the bit line BL is pull down to the ground by the sixth N-type transistor N6, the seventh P-type transistor P7 is turned on based on the bit line BL at the low logic level.

In other words, since the bit line BL is pulled low through the sixth N-type transistor N6, and the inverted bit line BLB is pulled high to approximately the periphery voltage VPER through the sixth P-type transistor P6 and the seventh P-type transistor P7, the states of the bit line BL and the inverted bit line BLB as indicated by the second area AR2 in FIG. 2 have been properly transitioned.

As shown in FIG. 1 and FIG. 2, a differential writing scheme for a memory is facilitated by pulling down the zero bit and pulling up the non-zero bit at the same time. Even when the periphery voltage VPER is much lower than the SRAM voltage VSRAM for power consumption reduction, the memory cell can be properly written by differentially driven.

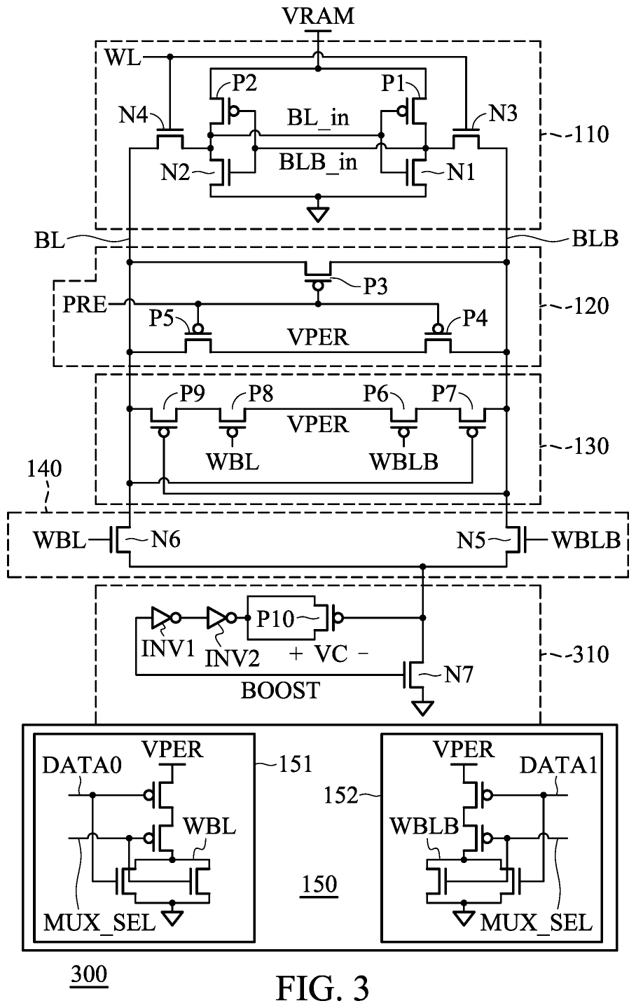

FIG. 3 is a circuit diagram of a memory circuit in accordance with another embodiment of the invention. Comparing the memory circuit 300 to the memory circuit 100 in FIG. 1, the memory circuit 300 further includes a negative boost circuit 310 coupled between the multiplexer 140 and the ground.

As shown in FIG. 3, the negative boost circuit 310 includes a seventh N-type transistor N7, a tenth P-type transistor P10, a first inverter INV1, and a second inverter INV2. The seventh N-type transistor N7 is coupled between the multiplexer 140 and the ground and controlled by a boost signal BOOST. The tenth P-type transistor is coupled as a capacitor and coupled to the multiplexer 140. The first inverter INV1 and the second inverter INV2 are coupled in series between the boost signal BOOST and the tenth P-type transistor P10.

According to an embodiment of the invention, when the boost signal BOOST is at the periphery voltage VPER to turn on the seventh N-type transistor N7 for coupling the multiplexer 140 to the ground, the capacitor voltage across the tenth P-type transistor P10 is approximately equal to the periphery voltage VPER. When the boost signal BOOST is at the ground level, the seventh N-type transistor N7 is turned off, and the tenth P-type transistor P10 provides a negative voltage to the multiplexer 140, where the negative voltage is approximately equal to the ground level minus a fraction of periphery voltage VPER. Since the negative boost circuit 310 lowers the lowest voltage level in the memory circuit 300, the lower periphery voltage VPER may be further compensated.

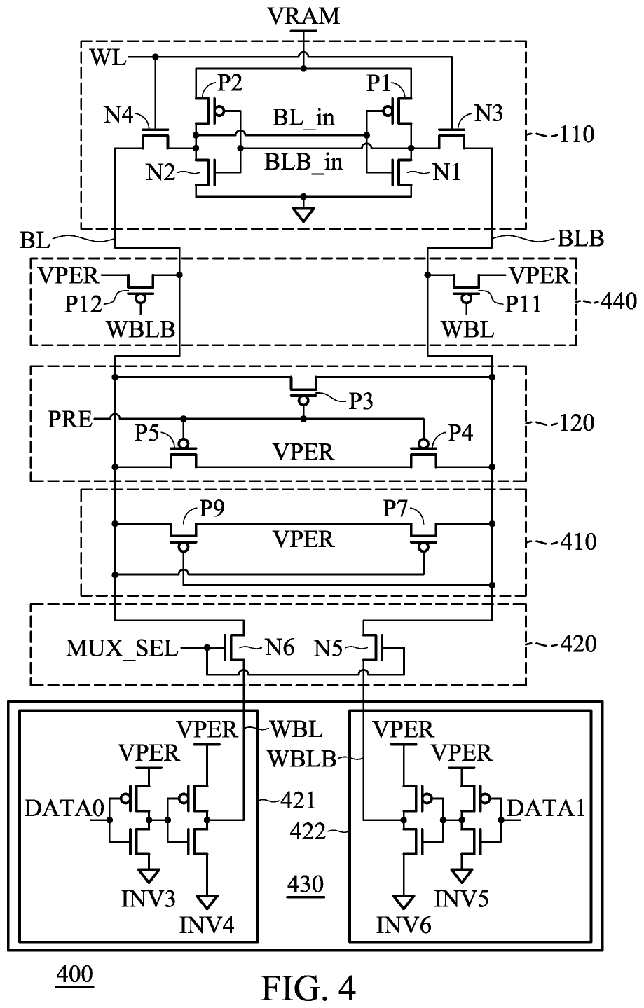

FIG. 4 is a circuit diagram of a memory circuit in accordance with yet another embodiment of the invention. Comparing the memory circuit 400 to the memory circuit 100 in FIG. 1, the memory circuit 400 includes the pull-up circuit 410, the multiplexer 420, and the write driver 430, which are different than the pull-up circuit 130, the multiplexer 140, and the write driver 150 in FIG. 1, and further includes a second pull-up circuit 440.

Comparing the pull-up circuit 410 to the pull-up circuit 130 in FIG. 1, the sixth P-type transistor P6 and the eighth P-type transistor P8 in FIG. 1 are eliminated. Therefore, the seventh P-type transistor P7 directly charges the inverted bit line BLB to approximately the periphery voltage VPER based on the bit line BL, or the ninth P-type transistor P9 directly charges the bit line BL to approximately the periphery voltage VPER based on the inverted bit line BLB. According to an embodiment of the invention, the seventh P-type transistor P7 and the ninth P-type transistor P9 act as a pair of cross-pullup transistors to pull up the bit line BL or the inverted bit line BLB.

Comparing the multiplexer 420 to the multiplexer 140 in FIG. 1, the fifth N-type transistor N5 and the sixth N-type transistor N6 are controlled by the select signal MUX_SEL. As illustrated in FIG. 4, the fifth N-type transistor N5 and the sixth N-type transistor N6 are turned on when the select signal MUX_SEL is at the high logic level, i.e., the periphery voltage VPER.

As shown in FIG. 4, the write driver 430 includes a first sub write driver 431 and a second sub write driver 432, where the first sub write driver 431 includes a third inverter INV3 and a fourth inverter INV4 coupled in series and the second sub write driver 432 includes a fifth inverter INV5 and a sixth inverter INV6 coupled in series. According to an embodiment of the invention, the third inverter INV3, the fourth inverter INV4, the fifth inverter INV5, and the sixth inverter INV6 are powered by the periphery voltage VPER. The first sub write driver 431 generates the write bit line WBL based on the input data DATA0, and the second sub write driver 432 generates the inverted write bit line WBLB based on the inverted input data DATA1.

The second pull-up transistor 440 includes an eleventh P-type transistor P11 and a twelfth P-type transistor P12. The eleventh P-type transistor P11 is controlled by the write bit line WBL and coupled between the periphery voltage VPER and the inverted bit line BLB. The twelfth P-type transistor P12 is controlled by the inverted write bit line WBLB and coupled between the periphery voltage VPER and the bit line BL. According to an embodiment of the invention, the second pull-up circuit 440 is configured to further pull up the non-zero bit to approximately the periphery voltage VPER.

For the simplicity of explanation, it is also assumed that the input data DATA0 is at the low logic level and the inverted input data DATA1 is at the high logic level, and that the internal bit line BL_in and the inverted internal bit line BLB_in originally store the high logic level and the low logic level respectively. Therefore, the write bit line WBL and the inverted write bit line WBLB generated by the write driver 430 are at the low logic level and the high logic level respectively.

As shown in FIG. 4, the write bit line WBL selects the bit line BL as the zero bit, and the inverted write bit line WBLB selects the inverted bit line BLB as the non-zero bit. Therefore, the first sub write driver 431 couples the sixth N-type transistor N6 to the ground, and the second sub write driver 432 provides the periphery voltage VPER to the fifth N-type transistor N5, so that a differential writing scheme is applied to the bit line BL and the inverted bit line BLB when the select signal is at the high logic level to turn on the sixth N-type transistor N6 and the seventh N-type transistor N7.

In addition, since the bit line BL is coupled to the ground through the sixth N-type transistor N6, the seventh transistor P7 is turned on for charging the inverted bit line BLB more close to the periphery voltage VPER. Moreover, the write bit line WBL being at the low logic level turns on the eleventh P-type transistor P11 for further charging the inverted bit line BLB.

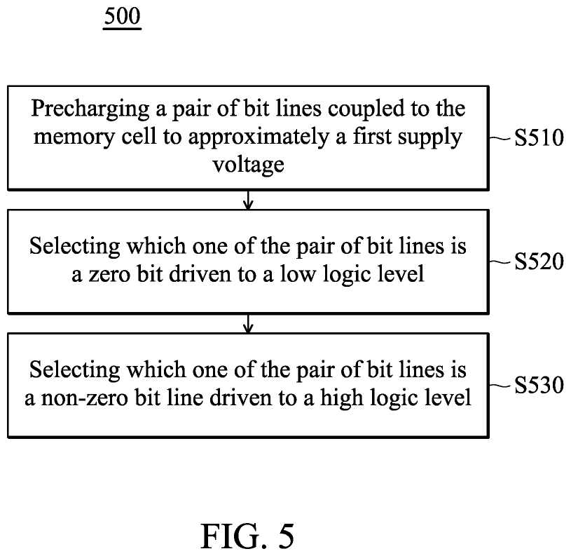

FIG. 5 is a flow chart 500 of a method for performing a write operation on a memory cell in accordance with an embodiment of the invention. As shown in FIG. 5, a pair of bit lines coupled to the memory cell 110 are precharged to approximately a first supply voltage to begin the write operation (Step S510). As illustrated in FIG. 1, FIG. 3, and FIG. 4, the precharge circuit 120 precharges the bit line BL and the inverted bit line BLB to approximately the periphery voltage VPER. According to an embodiment of the invention, the periphery voltage VPER may be less than the SRAM voltage VSRAM, which is supplied to the memory cell 110, for power consumption reduction.

After turning off the precharging of the pair of bit lines, which one of the pair of bit lines is a zero bit driven to the low logic level is selected (Step S520), and which one of the pair of bit lines is a non-zero bit line driven to the high logic level is also selected (Step S530).

As illustrated in FIG. 1 and FIG. 3, either the bit line BL or the inverted bit line BLB is selected to be a zero bit or a non-zero bit by the multiplexer 140 coupling the zero bit to the ground and the pull-up circuit 130 charging the non-zero bit.

As illustrated in FIG. 4, either the bit line BL or the inverted bit line BLB is selected to be a zero bit or a non-zero bit by coupling the zero bit to the ground by the multiplexer 420 and the first sub write driver 431 and charging the non-zero bit to approximately the periphery voltage VPER by the second sub write driver 432. In addition, the non-zero bit is further charged by the pull-up circuit 410 and the second pull-up circuit 440.

Memory circuits and methods for performing write operations on a memory cell are provided herein. Since a differential writing scheme is performed on the selected memory cell as provided herein, the robustness and the speed of performing write operations on a memory cell with lower periphery voltage can be improved simultaneously.

Although some embodiments of the present disclosure and their advantages have been described in detail, it should be understood that various changes, substitutions and alterations can be made herein without departing from the spirit and scope of the disclosure as defined by the appended claims. For example, it will be readily understood by those skilled in the art that many of the features, functions, processes, and materials described herein may be varied while remaining within the scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A circuit, comprising:
a memory cell;
a pair of bit lines, coupled to the memory cell;
a precharge circuit, coupled between the pair of bit lines, wherein the precharge circuit is configured to precharge each of the bit lines to approximately a first supply voltage to begin a write operation;
a multiplexer, configured to select which one of the pair of bit lines is a zero bit driven to a low logic level during the write operation and after the precharge circuit is turned off; and
a pull-up circuit, coupled to the pair of bit lines, wherein after the write operation begins, the pull-up circuit is configured to select which one of the pair of bit lines is a non-zero bit line driven to a high logic level.

2. The circuit as defined in claim 1, wherein the memory cell is supplied with a second supply voltage, wherein the second supply voltage either equals or exceeds the first supply voltage.

3. The circuit as defined in claim 2, wherein the pull-up circuit charges the non-zero bit to approximately the first supply voltage according to the input data.

4. The circuit as defined in claim 1, wherein the multiplexer further comprises:
a pair of pass transistors, wherein each of the pair of pass transistors is coupled to different one of the pair of bit lines, wherein the pair of pass transistors select which one of the pair of bit lines is the zero bit during the write operation by coupling the zero bit to a ground according to input data.

5. The circuit as defined in claim 4, wherein the pull-up circuit further comprises:
a first stack of pull-up transistors; and
a second stack of pull-up transistors;
wherein each of the first stack of pull-up transistors and the second stack of pull-up transistors is coupled to different one of the pair of bit lines;
wherein after the write operation begins, the first stack of pull-up transistors and the second stack of pull-up transistors select which one of the pair of bit lines is the non-zero bit line by charging the non-zero bit to approximately the first supply voltage according to the input data.

6. The circuit as defined in claim 5, further comprising:
a write driver, comprising:
a first logic gate, performing a first logic operation on the input data and a select signal to generate a zero-bit signal so as to turn on the corresponding one of the pair of pass transistors for coupling the zero bit to the ground; and
a second logic gate, performing a second logic operation on the input data and the select signal to generate an non-zero-bit signal so as to turn on the corresponding first or second stack of pull-up transistors for charging the non-zero bit to approximately the first supply voltage;
wherein the zero-bit signal is an inverse of the non-zero-bit signal.

7. The circuit as defined in claim 6, wherein the first stack of pull-up transistors comprises:
a first transistor, coupled to the first supply voltage and controlled by the non-zero-bit signal; and
a second transistor, coupled between the first transistor and the non-zero bit and controlled by the zero bit;
wherein the second stack of pull-up transistors comprises:
a third transistor, coupled to the first supply voltage and controlled by the zero-bit signal; and
a fourth transistor, coupled between the third transistor and the zero bit and controlled by the non-zero bit;
wherein the first transistor and the second transistor are turned on to drive the non-zero bit to the high logic level;
wherein the third transistor is turned off based on the zero-bit signal.

8. The circuit as defined in claim 6, wherein the pair of pass transistors select the zero bit coupled to the ground based on the zero-bit signal.

9. The circuit as defined in claim 1, further comprising:
a negative boost circuit, coupled between the multiplexer and the ground;
wherein when the negative boost circuit is turned on, the negative boost circuit couples the multiplexer to the ground;
wherein when the negative boost circuit is turned off, the negative boost circuit provides a negative voltage to the multiplexer.

10. The circuit as defined in claim 1, further comprising:
a write driver, coupled to the pair of bit lines through the multiplexer and configured to drive the zero bit to the low logic level and to drive the non-zero bit to the high logic level.

11. The circuit as defined in claim 10, wherein the multiplexer further comprises:
a pair of pass transistors, wherein each of the pair of pass transistors is coupled to different one of the pair of bit lines;
wherein when the memory cell is selected, the pair of pass transistors are turned on so that the write driver is coupled to the pair of bit lines.

12. The circuit as defined in claim 11, wherein the pull-up circuit further comprises:
a pair of pull-up transistors, wherein each of the pair of pull-up transistors is coupled to different one of the pair of bit lines; and
a pair of cross-pullup transistors, wherein each of the pair of cross-pullup transistors is coupled to different one of the pair of bit lines;
wherein one of the pair of pull-up transistors is configured to charge the non-zero bit to approximately the first supply voltage based on a zero-bit signal and the other of the pair of pull-up transistors is turned off;
wherein one of the pair of cross-pullup transistors is configured to charge the non-zero bit to approximately the first supply voltage based on the zero bit and the other of the pair of cross-pullup transistors is turned off;
wherein the write driver configured to drive the zero bit to the low logic level based on the zero-bit signal.

13. A method for performing a write operation on a memory cell, comprising:
precharging a pair of bit lines coupled to the memory cell to approximately a first supply voltage to begin the write operation;
after turning off precharging of the pair of bit lines, selecting which one of the pair of bit lines is a zero bit driven to a low logic level; and
after the write operation begins, selecting which one of the pair of bit lines is a non-zero bit line driven to a high logic level.

14. The method as defined in claim 13, wherein the memory cell is supplied with a second supply voltage, wherein the second supply voltage either equals or exceeds the first supply voltage.

15. The method as defined in claim 13, wherein the step of selecting which one of the pair of bit lines is the zero bit driven to the low logic level further comprises:
selecting which one of the pair of bit lines is the zero bit by coupling the zero bit to a ground according to input data.

16. The method as defined in claim 15, wherein the step of selecting which one of the pair of bit lines is the non-zero bit line driven to the high logic level further comprises:
selecting which one of the pair of bit lines is the non-zero bit line by charging the non-zero bit to approximately the first supply voltage according to the input data.

17. The method as defined in claim 16, further comprising:
performing a first logic operation on the input data and a select signal to generate a zero-bit signal;
coupling the zero bit to the ground according to the zero-bit signal; and
performing a second logic operation on the input data and the select signal to generate a non-zero-bit signal;
charging the non-zero bit with the first supply voltage according to the non-zero-bit signal;
wherein the zero-bit signal is an inverse of the non-zero-bit signal.

18. The method as defined in claim 17, wherein the non-zero bit is driven to the high logic level by a stack of pull-up transistors, wherein the step of selecting which one of the pair of bit lines is the non-zero bit line driven to the high logic level further comprises:
turning on the stack of pull-up transistors based on the zero bit and the non-zero-bit signal; and
charging the non-zero bit to approximately the first supply voltage due to the stack of pull-up transistors being turned on.

19. The method as defined in claim 13, wherein the step of selecting which one of the pair of bit lines is the zero bit driven to the low logic level further comprises:
generating a zero-bit signal based on input data by a write driver; and
providing the zero-bit signal to the zero bit to drive the zero bit to the low logic level.

20. The method as defined in claim 19, wherein the step of selecting which one of the pair of bit lines is the non-zero bit line driven to the high logic level further comprises:
generating a non-zero-bit signal based on the input data by using the write driver, wherein the non-zero-bit signal is an inverse of the zero-bit signal;
providing the non-zero-bit signal to the non-zero bit to drive the non-zero bit to the high logic level;
charging the non-zero bit to approximately the first supply voltage by using a pull-up transistor according to the zero-bit signal; and
further charging the non-zero bit to approximately the first supply voltage by a cross-pullup transistor according to the zero bit.
